(19) United States
(12) Patent Application Publication
(10) Pub. No.: US 2008/0123430 A1
(43) Pub. Date: May 29, 2008

(54) Non-volatile memory unit and array

(75) Inventor: Tzu-shih Yen, Taipei (TW)

Correspondence Address: BIRCH STEWART KOLASCH & BIRCH, PO BOX 747, FALLS CHURCH, VA, 22040-0747, US

(73) Assignee: Applied Intellectual Property Co., Ltd.

(21) Appl. No.: 11/476,645

(22) Filed: Jun. 29, 2006

(51) Int. Cl. H01L 29/68; G11C 11/34; G11C 7/00; H01L 29/788

(52) U.S. Cl. 365/185.23; 257/315; 365/205; 365/189.15; 257/E29.17; 257/E29.3

(57) ABSTRACT

A memory unit comprising a gate electrode, a gate dielectric under said gate electrode, an active area and a metal-semiconductor compound layer is provided. The active area comprises a first source/drain region, a second source/drain region, a normal field channel region formed under said gate electrode, a fringing field channel region formed between said first source/drain region and said normal field channel region, and an extension doping region formed between said second source/drain region and said normal field channel region. The metal-semiconductor compound layer is formed over said gate electrode, first source/drain region and second source/drain region.

### BACKGROUND OF THE INVENTION

1. Field of the Invention

The invention relates to a semiconductor device, and more particularly to a memory array with increased data throughput.

2. Description of the Related Art

Non-volatile read only memory (ROM) retains information even if power is cut off. Readable ROM types comprise Mask ROM, EPROM, EEPROM, and Flash Memory, of which Mask ROM cannot modify stored data, and is suited to large fabrications. Additionally, Flash Memory, using electrons entering and exiting floating gate to store information, is non-volatile and accessible, and can also retain information even when power is not provided.

FIG. 1a is a cross section of a conventional EEPROM memory unit during programming. When programming is performed, a high voltage is applied to a control gate electrode 105 and a drain region 101a, and then electrons penetrate through a gate oxide layer 102 to a floating gate electrode 103 from the drain region 101a in a silicon substrate 101.

FIG. 1b is a cross section of a conventional EEPROM memory unit during erasure. When erasure is performed, a negative or zero voltage is applied to the control gate electrode 105, and a high voltage is applied to the drain region 101a in the silicon substrate 101. Electrons then penetrate through the gate oxide layer 102 back to the drain region 101a from the floating gate electrode 103.

FIG. 1c is a cross section of a conventional programmed Mask ROM. The programming process is disclosed as follows. First, a silicon substrate 120 having a memory unit, such as a MOS transistor, thereon is provided. An oxide layer 122 is then formed over the silicon substrate 120. The memory unit comprises a gate electrode 123, such as a polysilicon layer, and source/drain regions 121a and 121b, such as n+ or p+ diffusion region, here, the source/drain regions 121a and 121b are n+ diffusion regions.

Next, a lithography process is performed using a code mask to form a patterned photoresist layer over a part of the gate electrode 123 and the source/drain regions 121a and 121b. Channel implantation onto the silicon substrate 120 having memory units is then performed to achieve the memory unit data coding.

When the gate electrode 123 is uncovered by the patterned photoresist, the memory unit is defined as logic “l” due to implantation of the channel region 124, to the contrary, when the gate electrode 123 is covered by the patterned photoresist, the memory unit is defined as logic “0”, because the channel region 124 cannot be implanted.

Implantation Programming is completed by implanting ions into channel region to adjust the threshold voltage. This process is performed after forming the MOS transistor, and before forming contacts or inter layer dielectrics (ILD).

As integration density is increased, reduced memory unit size, simplified device processing, and low data coding cost are required for fabricating modern Mask ROMs.

FIG. 1d is a cross section of a known One Time Programmable ROM or anti-fuse. The memory unit comprises a semiconductor substrate 130 having a gate dielectric layer 132 and a gate electrode 133 thereon and a source/drain extension area 131 therein under one side of the gate electrode 233, a spacer 134 on a sidewall of the gate electrode 133, two source/drain regions formed on the semiconductor substrate 130, and a silicide layer 135 over the gate electrode 133, wherein the source/drain extension area 131 is formed using the gate electrode 133 as a mask, and the source/drain region is formed by implanting the semiconductor substrate 130 using the gate electrode 133 and the spacer 134 as masks. After thermal process, the source/drain extension area 131 diffuses toward under the gate electrode 133, resulting in isolation between the gate electrode 133 and the source/drain extension area 131 by the gate dielectric layer 132a. The gate dielectric layer 132a can be broken down to create leakage by selectively applying high voltage, used as anti-fuse memory.

If the anti-fuse between the source/drain region and the gate electrode 133 is not breakdown, the electric leakage of the memory unit may decrease. When a normal voltage is applied to the gate electrode 133, the source/drain regions cannot be conducted, thus a little leakage current is generated and the accessed data therein is logic “0”. If the anti-fuse between the source/drain region and the gate electrode 133 is breakdown, the electric leakage of the memory unit may increase. When a normal voltage is applied to the gate electrode 133, high leakage current may occur, thus the accessed data therein is logic “1”. Thus, the data of the memory unit is accessed as logic “1” when the anti-fuse is breakdown, and the data of the memory unit is accessed as logic “0” when the anti-fuse is not breakdown.

As the memory unit illustrated in the above prior arts, one set of memory array can be read, programmed or erased on the basis of its own operational mechanisms in the conventional non-volatile memory units, that is, the nature of data storing functionality of these memory units has been determined during the array and circuit design stage without any possibility of changes.

### BRIEF SUMMARY OF THE INVENTION

The present invention provides a memory unit comprising a gate electrode, an active area and a metal-semiconductor compound layer. The active area comprises a first source/drain region, a second source/drain region, a normal field channel region formed under said gate electrode, a fringing field channel region formed between said first source/drain region and said normal field channel region, and an extension doping region formed between said second source/drain region and said normal field channel region. The metal-semiconductor compound layer is formed over said gate electrode, first source/drain region and second source/drain region.

In another exemplary embodiment of the invention, a memory unit comprises a gate electrode, an active area, a pre-determined code implantation region or a fringing field channel region formed between said first source/drain region and said normal field channel region, and a metal-semiconductor compound layer formed over said gate electrode, first source/drain region and second source/drain region. The active area further comprises a first source/drain region, a second source/drain region, a normal field channel region formed under said gate electrode, and an extension doping region formed between said second source/drain region and said normal field channel region.

In another exemplary embodiment of the invention, a memory unit comprises a gate electrode, an active area, a metal-semiconductor compound layer formed over said gate electrode, first source/drain region and second source/drain region, and a multi-layer dielectric spacer formed over said fringing field channel region to store electric charges. The active area further comprises a first source/drain region, a second source/drain region, a normal field channel region formed under said gate electrode, a fringing field channel region formed between said first source/drain region and said normal field channel region, and an extension doping region formed between said second source/drain region and said normal field channel region. The carriers can be injected from said fringing field channel and trapped in said dielectric spacer as charge trapping memory.

The invention further provides a memory array comprising a plurality of described memory units, a plurality of word lines coupled to the gate electrodes, a plurality of first source/drain lines or a plurality of first bit lines coupled to the first source/drain regions, and a plurality of second source/drain lines a plurality of second bit lines coupled to the second source/drain regions.

A detailed description is given in the following embodiments with reference to the accompanying drawings.

### BRIEF DESCRIPTION OF THE DRAWINGS

For a better understanding of the present invention, reference is made to a detailed description to be read in conjunction with the accompanying drawings, in which:

FIG. 1a is a cross section of a conventional EEPROM memory unit during programming.

FIG. 1b is a cross section of a conventional EEPROM memory unit during erasure.

FIG. 1c is a cross section of a conventional programmed Mask ROM.

FIG. 1d is a cross section of an anti-fuse ROM.

FIG. 2a is a cross section of a memory unit of the present invention.

FIG. 2b is a memory unit layout of the present invention.

FIG. 2c is a circuit symbol of a memory unit of the present invention.

FIG. 2d is a cross section of an electrically readable, writeable, and erasable ROM unit of the present invention.

FIG. 2e is a cross section of a Mask ROM unit of the present invention.

FIG. 2f is a cross section of a One-Time-Programmable or Anti-fuse ROM unit of the present invention.

FIG. 3a shows a single multi-function memory unit in the first embodiment of the present invention.

FIG. 3b shows a multi-function memory array in the first embodiment of the present invention.

FIG. 3c shows an equivalent circuit of the multi-function memory array in FIG. 3b.

FIG. 4a and 4b show two single multi-function memory units in the second embodiment of the present invention.

FIG. 4c shows a multi-function memory array in the second embodiment of the present invention.

FIG. 4d shows an equivalent circuit of the multi-function memory array in FIG. 4c.

FIGS. 5a and 5b show two single multi-function memory units in the third embodiment of the present invention.

FIG. 5c shows a multi-function memory array in the third embodiment of the present invention.

FIG. 5d shows-an equivalent circuit of the multi-function memory array in FIG. 5c.

FIGS. 6a and 6b show two single multi-function memory units in the fourth embodiment of the present invention.

FIG. 6c shows a multi-function memory array in the fourth embodiment of the present invention.

FIG. 6d shows an equivalent circuit of the multi-function memory array in FIG. 6c.

FIGS. 7a and 7b show two single multi-function memory units in the fifth embodiment of the present invention.

FIG. 7c shows a multi-function memory array in the fifth embodiment of the present invention.

FIG. 7d shows an equivalent circuit of the multi-function memory array in FIG. 7c.

FIG. 8 shows a driving circuit, a sensing circuit and a controller connected to a memory array in the present invention.

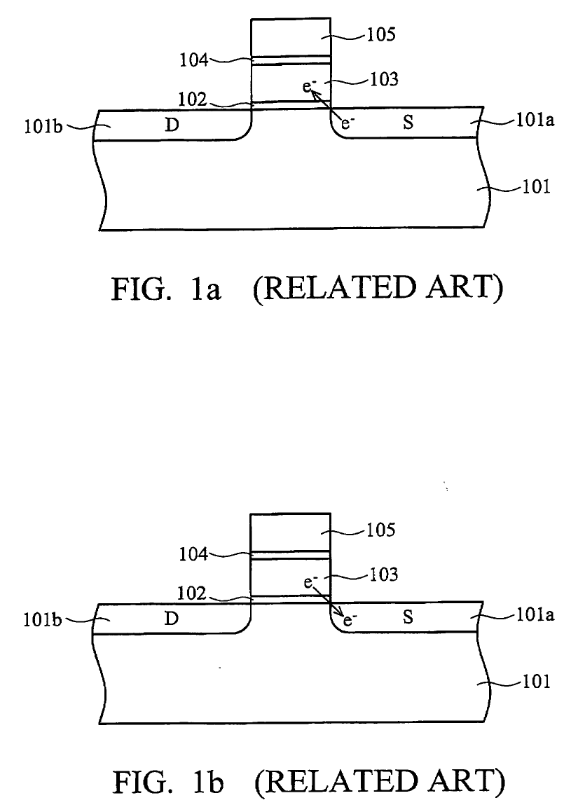

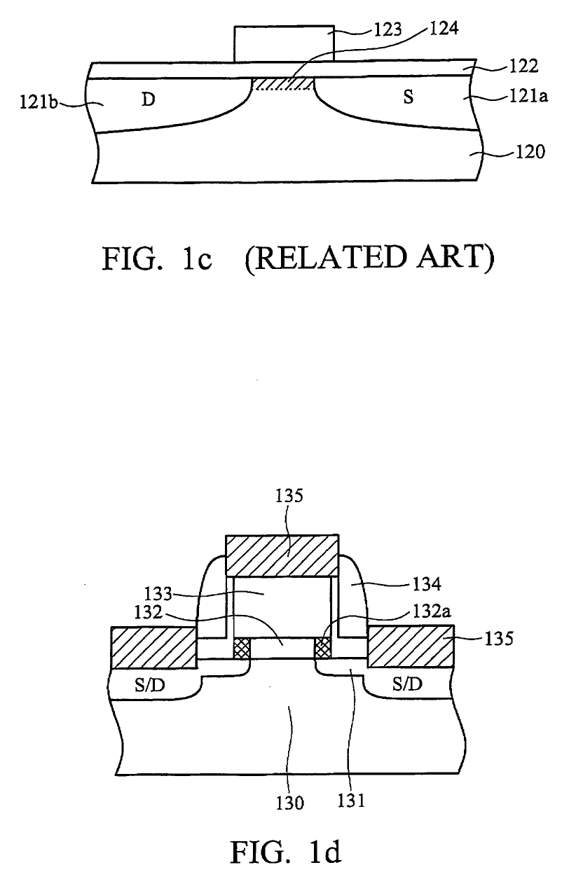

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

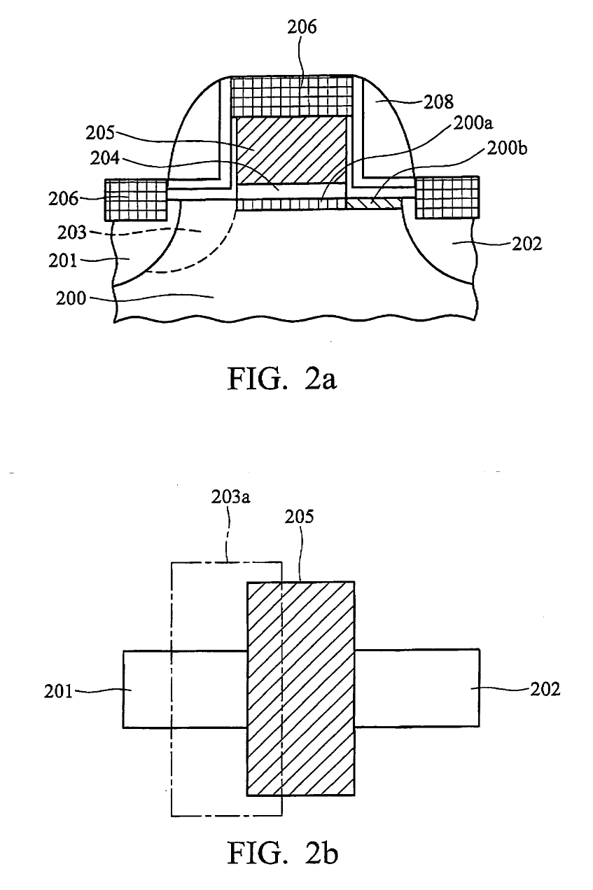

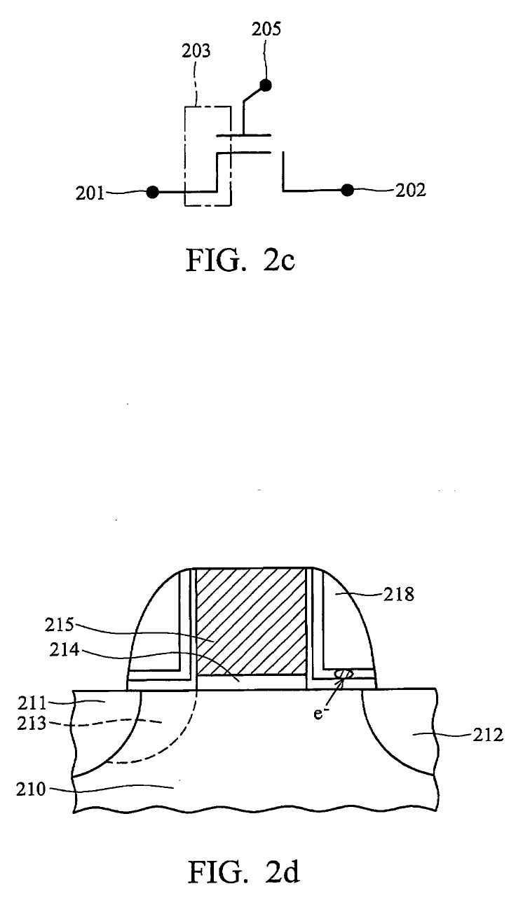

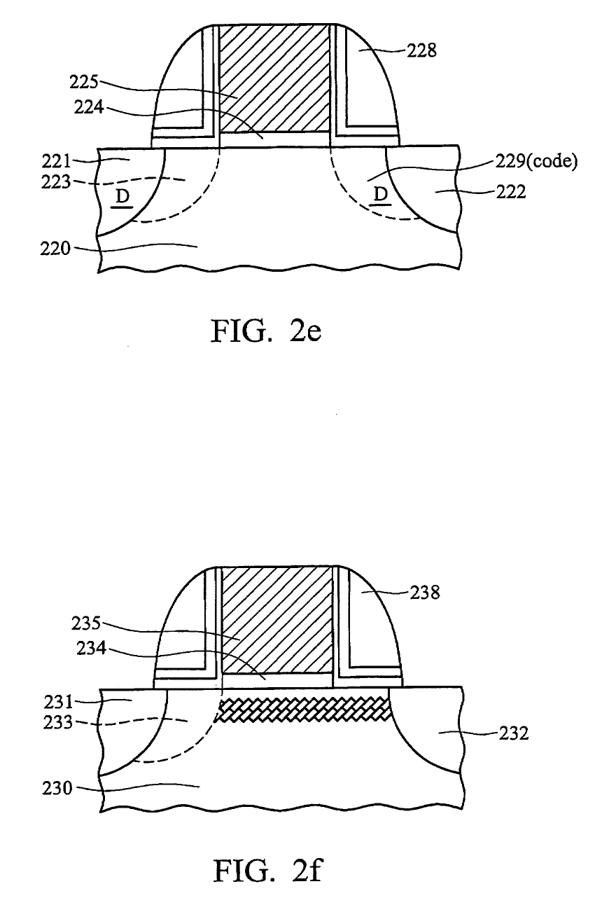

FIG. 2a is a cross section of the memory unit of the present invention. The memory unit comprises a semiconductor substrate 200 having a normal field channel 200a, a fringing field channel 200b, a source 201, a drain region 202 and an extension doping region 203 therein, a gate electrode 205, such as a polysilicon layer, on the normal field channel 200a, a gate dielectric layer 204, such as a gate oxide layer, between the gate electrode 205 and the semiconductor substrate 200, a multi-layer dielectric spacer 208, on sidewalls of the gate electrode 205 wherein the multi-layer dielectric spacer on the fringing field channel 200b is used to store electrons or electric charges, and an optional metal-semiconductor compound layer 206, such as suicides, over the gate electrode 205 and the source/drain region 201 and 202. The memory unit further comprises a dielectric layer, such as an oxide layer, over the semiconductor substrate 200 and the above elements, and a contact plug filled with a conductive layer in the dielectric layer to connect the source/drain region installed between the gate electrode and a subsequently formed bit line.

FIG. 2b is a memory unit layout of the present invention. The memory layout comprises a semiconductor substrate (not shows in this figure) having a source 201, a drain 202, an extension implantation mask 203a and a gate electrode 205.

FIG. 2c is a circuit symbol of a memory unit of the present invention. The memory symbol comprises a source 201, a drain 202, an extension region 203 and a gate electrode 205.

FIG. 2d is a cross section of an electrically readable, writeable, and erasable ROM (EEPROM) of the present invention. The memory unit comprises a semiconductor substrate 210 having a source 211, a drain region 212 and an extension doping region 213 therein, a gate electrode 215, such as a polysilicon layer, on the semiconductor substrate 200, a gate dielectric layer 214, such as a gate oxide layer, between the gate electrode 215 and the semiconductor substrate 210, an optional silicide layer (not shown in FIG. 2d) over the gate electrode 215, source 211 and drain 212 regions, a multi-layer dielectric spacer 218, such as a stack of an oxide layer, a nitride layer and an oxide layer wherein the drain-side spacer is used to store electrons or electric charges. The memory unit further comprises a dielectric layer, such as an oxide layer, over the semiconductor substrate 210 and the above elements, and a contact plug filled with a-conductive layer in the dielectric layer to connect the source/drain region installed between the gate electrode and a subsequently formed bit line.

FIG. 2e is a cross section of the Mask ROM of the present invention. The memory unit comprises a semiconductor substrate 220 having a source 222, a drain region 221, a gate dielectric layer 224 and a gate electrode 225 thereon and an extension doping region 223 therein near one side of the gate electrode 225, a dielectric spacer 228, and an optional silicide layer (not shown in FIG. 2e) over the gate electrode 225 and source 221 and drain 222 regions, wherein the code doping area 229 is formed using ion implantation through a photoresist layer patterned by a code mask and the gate electrode 225 as masks and the source and drain regions are formed by implanting the semiconductor substrate 220 using the gate electrode 225 and the spacer 228 as masks. The code doping area 229 and the extension doping region 223 can be simultaneously formed using the same masks and implantation.

If the code doping area 229 is not formed between the source region 222 and the gate electrode 225, the threshold voltage of the memory unit may increase. When accessing data, if a normal read voltage is applied to the gate electrode 225, the channel between the source and drain regions can not be conducted, producing a relatively low leakage current, thus the logic “0” is accessed. If the code doping area 229 is formed between the source region 222 and the gate electrode 225, the threshold voltage of the memory unit may decrease. When accessing data, if a normal read voltage is applied to the gate electrode 225, the channel between the source and drain regions can be conducted, and logic “1” is accessed. Thus, the memory unit is accessed as logic “1”, when the code doping area 229 is formed, and the memory unit is accessed as logic “0”, when the code doping area 229 is not formed.

FIG. 2f is a cross section of the One-Time-Programmable ROM or Anti-fuse of the present invention. The memory unit comprises a semiconductor substrate 230 having a source region 231, a drain region 232, a gate dielectric layer 234, a gate electrode 235, an extension doping region 233 under one side of the gate electrode 235, a dielectric spacer 238 on sidewalls of the gate electrode 235, an optional silicide layer (not shown in FIG. 2f) over the gate electrode 235, the source 231 and drain 232 regions, wherein the extension doping region 233 is formed using the gate electrode 235 as a mask, and the source/drain regions are formed by implanting the semiconductor substrate 230 using the gate electrode 235 and the spacer 238 as masks. The conductivity between the source region and drain region can be increased by applying electrical voltage or current between the source 231 and drain 232 regions and used as One-Time-Programmable ROM or Anti-fuse.

When accessing data, if a relatively high voltage difference is applied between the source 231 and drain regions 232, the channel conductivity between the source/drain regions can be increased, producing relatively high leakage current, thus the logic “1” is accessed. If the conductivity between the source/drain regions in the anti-fuse is at initial state, the read out current of the memory unit may remain relatively low, whereby the logic “0” is accessed. Thus, the memory unit is accessed as logic “1”, when the anti-fuse is reduced in resistance, and the memory unit is accessed as logic “0”, when the anti-fuse is not reduced in resistance.

### First Embodiment

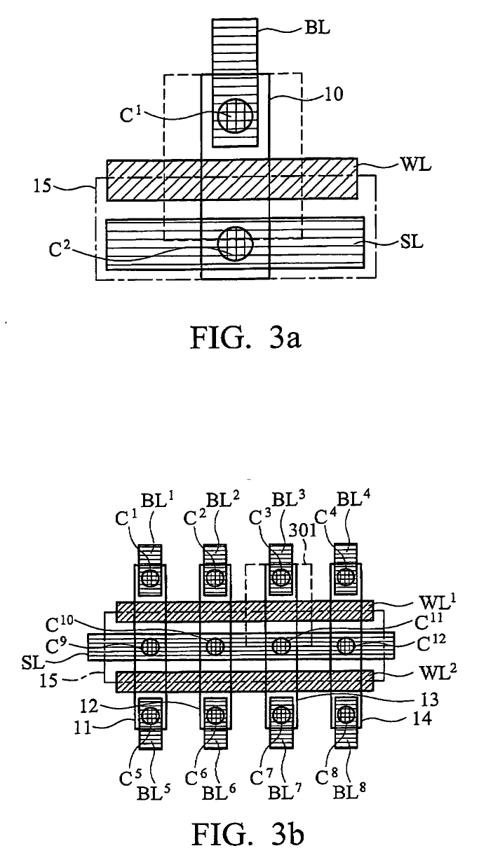

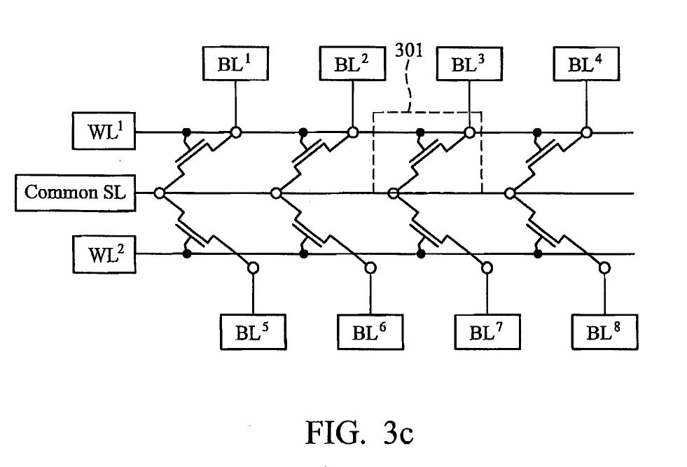

FIG. 3a shows a single memory unit in the first embodiment of the present invention, FIG. 3b shows a memory array in the first embodiment of the present invention, and FIG. 3c shows an equivalent circuit of the memory array in FIG. 3b.

Referring to FIG. 3a, a semiconductor substrate (not shown) having the memory unit shown in FIG. 2d, 2e, or 2f is provided, with an active area 10 defined therein. The memory unit comprises an active area 10, a word line WL, a bit line BL, a second bit line or source line SL, an extension implantation region 15, a first connection point C¹, and a second connection point C², wherein the word line is the gate electrode, and the connection points are contact plugs.

The word line WL is perpendicular to the bit line BL and paralleled to the source line SL. The bit line BL is perpendicular to the source line SL, and the bit line BL and the source line SL are separated by the word line WL. The first connection point C¹ electrically connects to the bit line BL, and the second connection point C² electrically connects to the source line SL, wherein the first connection point C¹ and the second connection point C² are located on different sides of the word line WL¹. The active area 10 is formed under the above elements. The active area 10 is rectangular as “I”-shape, and the first connection point C¹ and the second connection point C² are respectively located on its two ends of the active area 10.

Referring to FIG. 3b, the memory array comprises a common source line SL, word lines WL¹, and WL², bit lines BL¹, BL², BL³, BL⁴, BL⁵, BL⁶, BL⁷ and BL⁸, connection points C¹, C², C³, C⁴, C⁵, C⁶, C⁷, C⁸, C⁹, C¹⁰, C¹¹ and C¹², memory unit 301, and 4 active areas 11, 12, 13 and 14, wherein the memory unit 301 is an example of the single-bit memory unit shown in FIG. 3a. A common source line SL is commonly connected with source-side connection points, C⁹, C¹⁰, C¹¹ and C¹², which can be jointly used by adjacent memory unit, for example, the second connection point C¹¹ is jointly used by the memory unit 301 and its adjacent memory unit to form the electrical connection, as shown in the array equivalent circuit of FIG. 3c.

### Second Embodiment

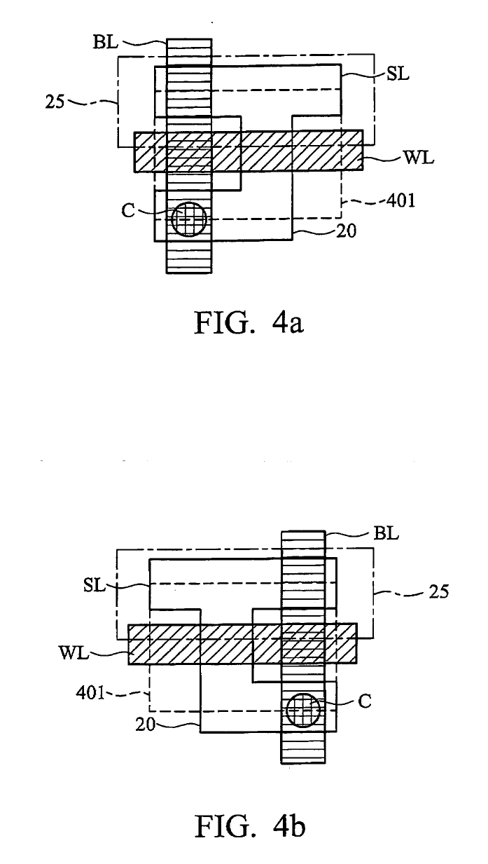

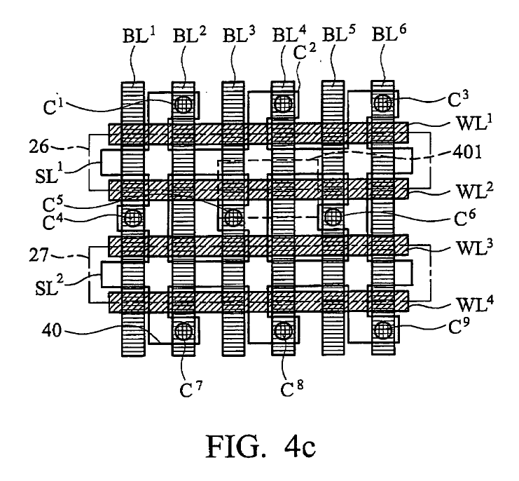

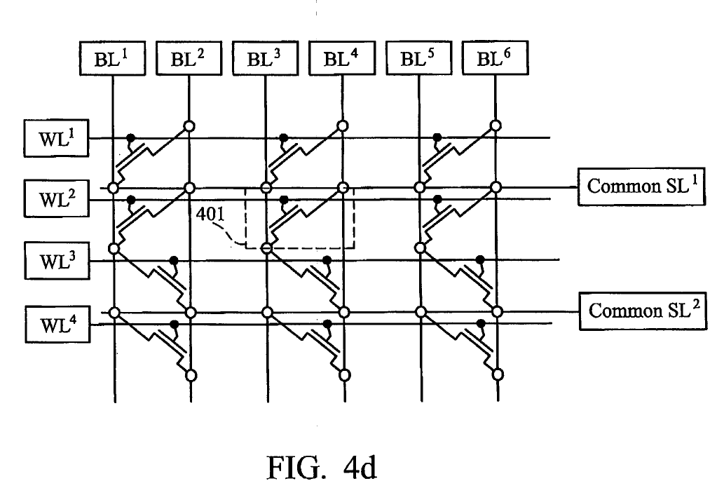

FIG. 4a and 4b show two memory units in the second embodiment of the present invention, FIG. 4c shows a memory array in the second embodiment of the present invention, and FIG. 4d shows an equivalent circuit of the memory array in FIG. 4c.

Referring to FIG. 4a, a semiconductor substrate (not shown) having the memory unit shown in FIG. 2d, 2e or 2f is provided, with an active area 20 defined therein.

The memory unit comprises an active area 20, a word line WL, a bit line BL, an extension implantation region 25, a connection point C, and a source line SL, wherein the word line is the gate electrode, and the connection point is the contact plug.

The word line WL and source line SL are perpendicular to the bit line BL. The word line WL is parallel to the source line SL. The connection point C electrically connects to the bit line BL, wherein the connection point C and the source line BL are separated by the word line WL. The active area 20 is formed under the above elements. As shown in FIG. 4a, the active area 40 is “J”-shaped, comprising a main area and two extension areas, with the long extension area and short extension area perpendicularly connecting to two ends of the main area respectively. One end of the main area is connected to the middle portion of the long extension area. The other end of the main area is connected to one end of the short extension area. The connection point C is located on the short extension area of the active area 20. FIG. 4b illustrates a mirror-imaging unit of the memory unit in FIG. 4a.

Referring to FIG. 4c, the memory array comprises word lines WL¹, WL², WL³, and WL⁴, bit lines BL¹, BL², BL³, BL⁴, BL⁵ and BL⁶, extension implantation regions 26 and 27, connection points C¹, C², C³, C⁴, C⁵, C⁶, C⁷, C⁸ and C⁹, and active areas 40, wherein the memory unit 401 is a single-bit memory unit shown in FIG. 4a. Each connection point can be jointly used by adjacent memory units, for example, the connection point C⁵ is jointly used by the memory unit 401 and its adjacent memory unit to form the electrical connection, as shown in the array equivalent circuit of FIG. 4d.

### Third Embodiment

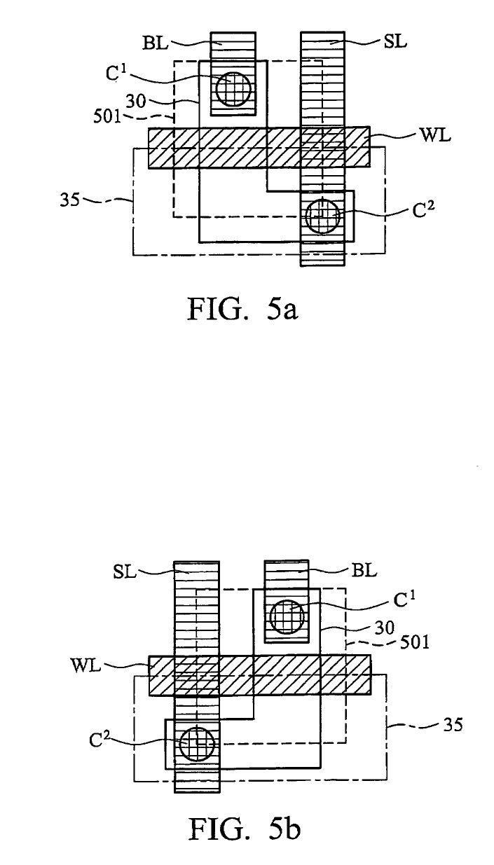

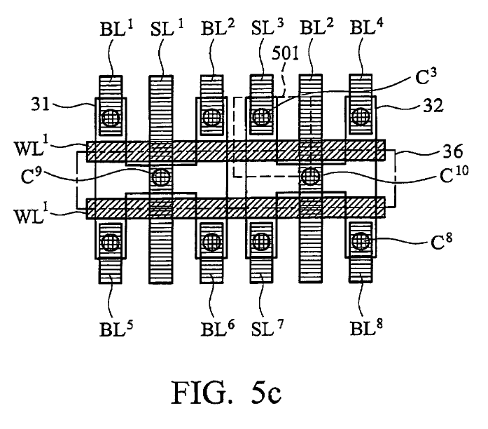

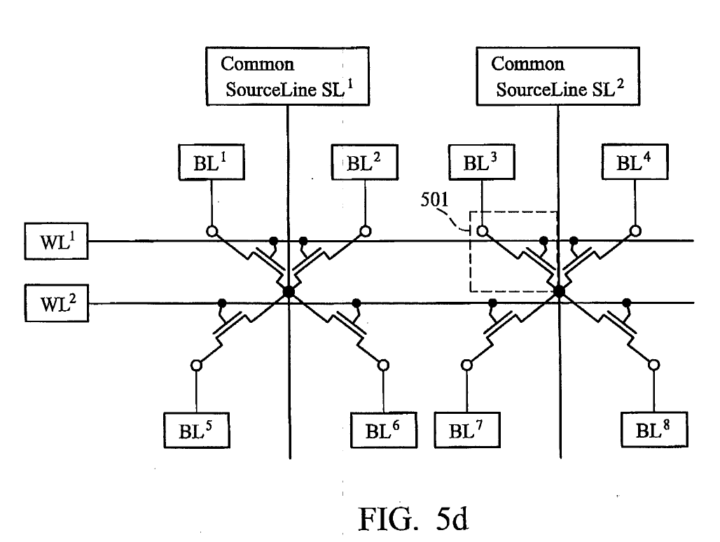

FIG. 5a and 5b show two single memory units in the third embodiment of the present invention, FIG. 5c shows a memory array in the third embodiment of the present invention, and FIG. 5d shows an equivalent circuit of the memory array in FIG. 5c.

Referring to FIG. 5a and 5b, a semiconductor substrate (not shown) having the memory unit shown in FIG. 2d, 2e or 2f is provided, with an active area 30 defined therein.

Referring to FIG. 5a, one of the two memory units is disclosed as follows. The memory unit comprises an active area 30, a word line WL, a bit line BL, a second bit line or source line SL, an extension implantation region 35, a first connection point C¹, and a second connection point C², wherein the word line is the gate electrode, and the connection points are contact plugs.

The word line WL is perpendicular to the bit line BL and the source line SL. The bit line BL is parallel to the source line BL. The first connection point C¹ electrically connects to the bit line BL, and the second connection point C² electrically connects to the source line SL, wherein the first connection point C¹ and the second connection point C² are separated by the word line WL. The active area 30 is formed under the above elements. The active area 30 is “L”-shaped, comprising a main area and an extension area, with one end of the main area perpendicularly connecting to one end of the extension area. The main area is perpendicular to the word line WL corresponding thereto. The extension area is parallel to the word line corresponding thereto. And the first connection point C¹ and the second connection point C² are respectively located on the main area and extension area of the active area 30. FIG. 5b illustrates the mirror-imaging unit of the memory unit in FIG. 5a.

Referring to FIG. 5c, the memory array comprises word lines WL¹, and WL², source lines SL¹, and SL², bit lines BL¹, BL², BL³, BL⁴, BL⁵, BL⁶, BL⁷ and BL⁸, connection points C¹, C², C³, C⁴, C⁵, C⁶, C⁷, C⁸, C⁹ and C¹⁰, an extension implantation region 36, and active areas 31 and 32, wherein the memory unit 501 is a single-bit memory unit shown in FIG. 5a or 5b. Each connection point can be jointly used by four adjacent memory units, for example, the connection point C¹⁰ is jointly used by the memory unit 501 and its adjacent three memory units to form the electrical connection, as shown in the array equivalent circuit of FIG. 5d.

### Fourth Embodiment

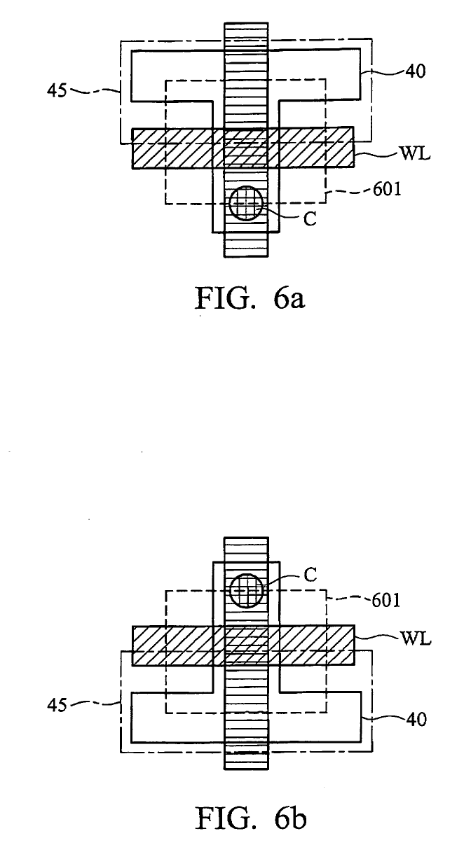

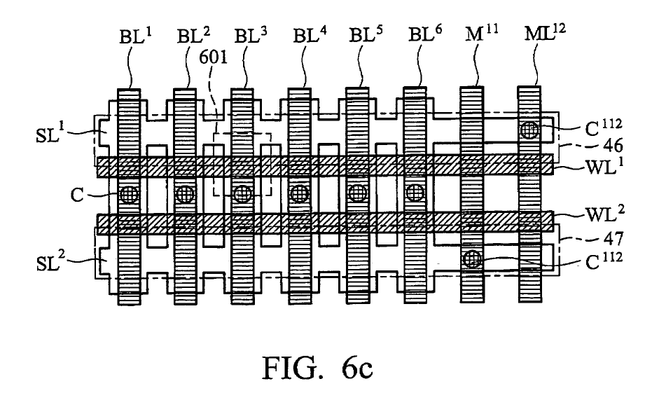

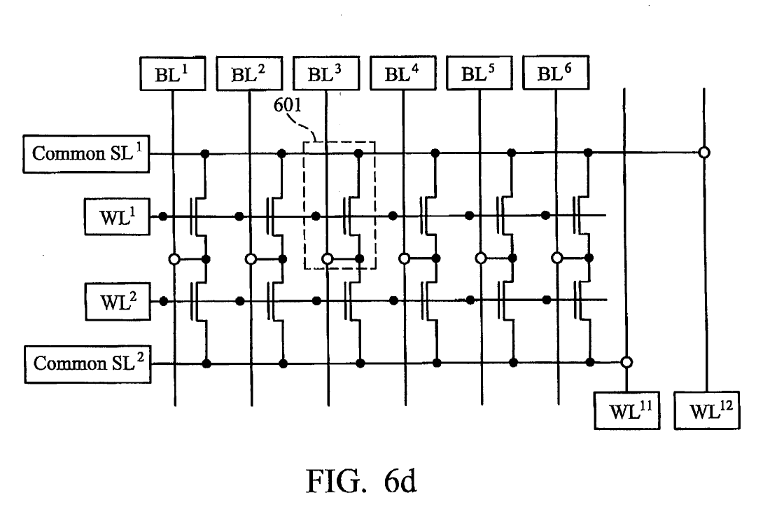

FIG. 6a and 6b show two memory units in the fourth embodiment of the present invention, FIG. 6c shows a memory array in the fourth embodiment of the present invention, and FIG. 6d shows an equivalent circuit of the memory array in FIG. 6c.

Referring to FIG. 6a and 6b, a semiconductor substrate (not shown) having a memory unit shown in FIG. 2d, 2e or 2f is provided, with an active area 40 defined therein.

Referring to FIG. 6a and FIG. 6b, one of the two memory units is disclosed as follows. The memory unit comprises an active area 40, a word line WL, a bit line BL, an extension implantation region 45, a connection point C, wherein the word line is the gate electrode, and the connection point is contact plug.

The word line WL is perpendicular to the bit line BL. The connection point C electrically connects to the first bit line BL. The active area 40 is formed under the above elements. The active area 40 is “T”-shaped, comprising a main area and an extension area, with one end of the main area connecting to the middle of the extension area. The main area is parallel to the bit line BL corresponding thereto. The extension area is the common source line and parallel to the word line corresponding thereto. FIG. 6b illustrates the mirror-imaging unit of the memory unit in FIG. 6a.

Referring to FIG. 6c, the memory array comprises word lines WL¹ and WL², bit lines BL¹, BL², BL³, BL⁴, BL⁵, and BL⁶, connection points C¹, C², C³, C⁴, C⁵, C⁶, C¹¹¹ and C¹¹², extension implantation regions 46 and 47 and active areas 41, wherein the memory unit 601 is a single memory unit shown in FIG. 6a or 6b. Each connection point corresponding to the drain area can be jointly used by two adjacent memory units in the same column, and the source area installed on the same row can be jointly used by each memory unit in the same row. Additionally, common source lines SL¹, and SL² connect to the additional metal line M¹¹ or M¹²by the connection point C¹¹¹ or C¹¹². Referring to FIG. 6d, the connection point C³ is jointly used by the memory unit 601 and its adjacent memory unit in the same column to form the electrical connection, and the source area, such as source line SL¹, installed on the same row can be jointly used by each memory unit in the same row, as shown in the array equivalent circuit of FIG. 6d. Additionally, memory units connect to the additional metal line M¹¹ or M¹² by the connection point C¹¹¹ or C¹¹².

### Fifth Embodiment

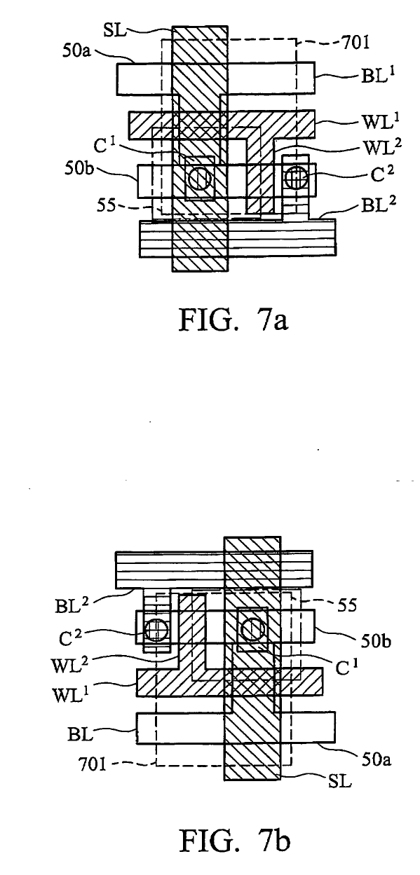

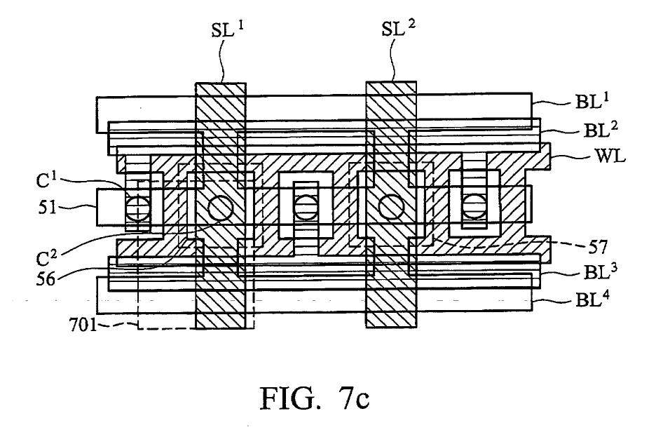

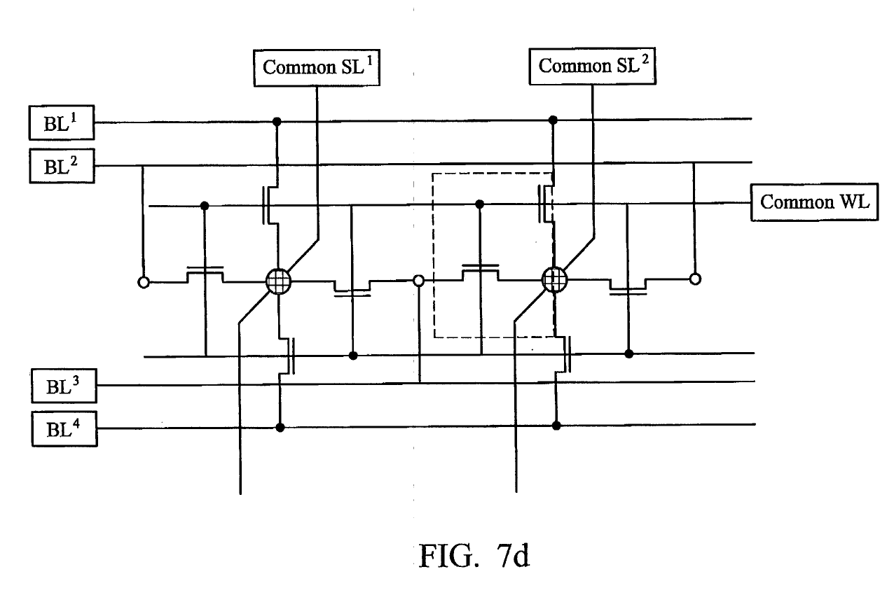

FIG. 7a and 7b show two examples of the multi-bit combination of T-shaped and I-shaped memory units in the fifth embodiment of the present invention, FIG. 7c shows a memory array in the fifth embodiment of the present invention, and FIG. 7d shows an equivalent circuit of the memory array in FIG. 7c.

Referring to FIG. 7a and 7b, a semiconductor substrate (not shown) having a two-bit memory unit shown in FIG. 2d, 2e or 2f is provided, with an active area 50 defined therein.

Referring to FIG. 7a, the two-bit memory unit is disclosed as follows. The two-bit memory unit comprises a “T”-shaped active areas 50a, a “I”-shaped active areas 50b, word lines WL¹ and WL², a source line SL, an extension implantation region 55, bit line BL¹ and BL², connection point C¹ and C² wherein the word lines are perpendicularly connected as the gate electrode, and the connection points are contact plugs.

The source line SL is perpendicular to the bit lines BL¹ and BL², wherein the first bit line BL¹ is formed by a portion of “T”-shaped active areas 50a. The first word line WL¹ is perpendicular to the bit line BL¹. The second word line WL² is perpendicular to the “I”-shaped active area 50b. The first connection point C¹ is connected to the source line SL and located on one side of the “I”-shaped active area 50b. The second connection point C² is connected to the bit line BL² and located on one side of the “I”-shaped active areas 50b electrically connects to the first bit line BL¹. The active areas 50a and 50b are formed under the above elements. The active area 50 is the combination of a I-shaped active area, comprising a first main area 50b and T-shaped active area 50a, comprising a second main area and a extension area, with one end of the second main area 50a coupled to one end of the first main area 50a and the other end of the second main area connecting to the middle of the extension area. The first and the second main areas are parallel to both bit lines and perpendicular to the source line corresponding thereto. The extension area is parallel to the bit lines corresponding thereto.

Referring to FIG. 7c, the memory array comprises a common word line WL, source lines SL¹ and SL², bit lines BL¹, BL², BL³ and BL⁴, connection points C¹, C², C³, C⁴ and C⁵, extension implantation regions 56 and 57, and active areas 51, wherein the memory unit 701 is a single two-bit memory unit shown in FIG. 7a or 7b. Referring to the memory unit 701 in FIG. 7c, the connection point C corresponding to the drain area can be jointly used by the adjacent memory unit, and the source region of each unit can be jointly used by the other memory unit and coupled to a common source line SL¹ through a connect point C² as shown in the array equivalent circuit of FIG. 7d.

The present invention provides multiple non-volatile memory purposes in a memory unit to store data, that is, Anti-fuse, Electrically Readable-Writable-Erasable ROM and Mask ROM, depending upon circuits provided. The flexibility for various memory purposes is improved using the same memory array of this invention.

### Sixth Embodiment

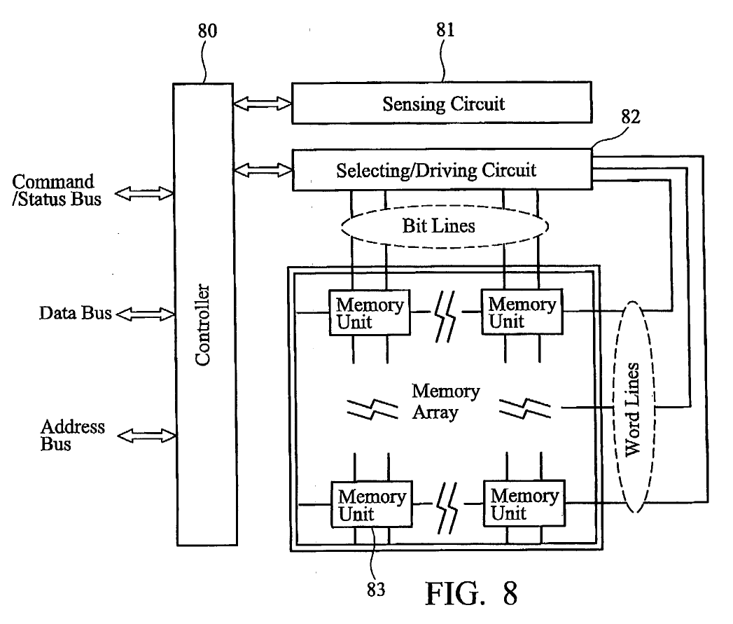

Referring to FIG. 8, the memory array as disclosed in the first, second, third, fourth and fifth embodiments, further comprises a selecting/driving circuit 82, connected to a plurality of word lines and a plurality of bit lines of memory units, a sensing circuit 81, connected to a plurality of bit lines, and a controller 80 for executing a memory operation on the memory units, such as memory unit 83, connected to the selecting/driving 82 and sensing circuits 81, for receiving a command from an external data bus or a command bus, and generating a plurality of control signals to the driving and sensing circuits based on the received command, wherein the controller 80 is also able to receive an address from the external address bus, and output the data stored in the memory array.

The memory array further comprises an over-writing circuit (not shown in FIG. 8) coupled to the word line, first bit line and second bit line, wherein the over-writing circuit provides over-write signals to select memory units and permanently alter the conductivity between the first bit line and second bit line, and as a programmed One Time Programmable ROM.

The memory array according to the above, wherein the controller is capable of performing complete or partial functions of an initializing operation, a reading operation, a programming operation, an erasing operation, a program-verifying operation and an erase-verifying operation, a testing operation and repairing operation.

The operations described in this disclosure, such as reading operation, programming operation and others, can be applied to the memory unit of the described six embodiments, and the detailed operations are described as following. The initializing operation comprises selecting at least one memory unit, applying a first initializing signal to a word line of the memory unit, applying a second initializing signal to a first bit line of the memory unit, and applying a third initializing signal to a second bit line of the memory unit when the output current of the memory unit is lower than a predetermined current level. The reading operation comprises selecting one memory unit, applying a first reading signal to the word line of the memory unit, applying a second reading signal to one of the first and the second bit lines of the memory unit, and coupling another one of the first and the second bit lines of the memory unit to the ground or the same potential as the semiconductor substrate. The programming operation comprises selecting at least one memory unit, applying a first programming signal to the word line of the memory unit, applying a second programming signal to one of the first and the second bit lines of the memory unit, and coupling another one of the first and the second bit lines of the memory unit to the ground or the same potential as the semiconductor substrate. The program- verifying operation comprises selecting at least one memory unit, sensing the output current of the memory unit, and applying a programming operation to the memory unit if the output current is higher than a predetermined current level. The erasing operation comprises selecting at least one memory unit, applying a first erasing signal to the word line of the memory unit, and applying a second erasing signal to at least one of the first and the second bit lines of the memory unit. The erase-verifying operation comprises selecting at least one memory unit, sensing the output current of the memory unit, and applying an erasing operation to the memory unit if the output current is lower than a predetermined current level. The self-testing operation comprises selecting at least one memory unit, applying a first self-testing signal to a word line of the memory unit, applying a second self-testing signal to the first bit line of the memory unit, applying a third self-testing signal to the second bit line of the memory unit, and when the output current of the memory unit is out of a predetermined current range, the controller outputs an error or damaged signal. The repairing operation comprises switching off a word line or a bit line of damaged memory units, and selecting and switching on a redundant word line or a redundant bit line with memory redundancy for replacing the word line or the bit line of damaged memory units.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A memory unit, comprising:
a gate electrode;
a gate dielectric under said gate electrode;
an active area, comprising:
a first source/drain region;
a second source/drain region;
a normal field channel region formed under said gate electrode;
a fringing field channel region formed between said first source/drain region and said normal field channel region; and
an extension doping region formed between said second source/drain region and said normal field channel region; and
a metal-semiconductor compound layer formed over said gate electrode, first source/drain region and second source/drain region.

2. The memory unit as claimed in claim 1, wherein the active area is I-shape and perpendicular to a world line.

3. The memory unit as claimed in claim 1, wherein the active area is L-shape and comprises a main area and an extension area, wherein one end of the main area connects to and perpendicular to the extension area, and said main area is perpendicular to said gate electrode, and said first source/drain region is in a part of the main area, and the second source/drain region is in the extension area and a part of the main area.

4. The memory unit as claimed in claim 1, wherein the active area is J-shape and comprises a main area and a first extension area and a second extension area, with said two extension areas perpendicularly connecting to two ends of the main area respectively, and the main area of active area is perpendicular to said gate electrode, the first source/drain region is in said first extension area and in a part of the main area, and the second source/drain region is in said second extension area and a part of the main area.

5. The memory unit as claimed in claim 1, wherein the active area is T-shape and comprises a main area and an extension area, wherein the end of the main area connects to the middle of the extension area, and the active area is parallel to the first source/drain line or the first bit line corresponding thereto, and the extension area is parallel to the word line corresponding thereto, and the first source/drain region is in a part of the main area, and the second source/drain region is in the extension area and a part of the main area.

6. A plurality of memory units as claimed in claim 1, wherein their active area comprises I-shape, J-shape, L-shape, T-shape or the combination thereof.

7. A memory array, comprising:
a plurality of word lines;
a plurality of first bit lines or first source/drain lines;
a plurality of second bit lines or second source/drain lines; and
a plurality of memory units, each memory unit comprising:
a gate electrode coupled to one word line;
a gate dielectric under said gate electrode;
an active area, comprising:
a first source/drain region coupled to one first bit line or first source/drain line;
a second source/drain region coupled to one second bit line or second source/drain line;
a normal field channel region formed under said gate electrode;
a fringing field channel region formed between said first source/drain region and said normal field channel region; and
an extension doping region formed between said second source/drain region and said normal field channel region; and
a metal-semiconductor compound layer formed over said gate electrode, first source/drain region and second source/drain region.

8. The memory array as claimed in claim 7, further comprising a circuit coupled to at least one first bit line and at least one second bit line, wherein the circuit provides electrical signals to alter and sense the conductivity between said first bit line and second bit line, is a One Time Programmable ROM

9. The memory array as claimed in claim 7, further comprising:
a selecting/driving circuit coupled to the word lines and the bit lines to select corresponding memory units based on predetermined addresses;
a sensing circuit coupled to the selecting/driving circuit to amplify signals of data stored in the corresponding memory units; and
a controller coupled to the selecting/driving circuit and the sensing circuit to perform memory operations on the memory units.

10. The memory array as claimed in claim 9, wherein the controller performs at least one of a plurality of operating functions including a reading operation, a programming operation, a program-verifying operation, a self-testing operation and a repairing operation; wherein
the reading operation comprises:
selecting at least one memory unit;
applying a first reading signal to the word line of the memory unit;
applying a second reading signal to one of the first and the second bit lines of the memory unit;
applying a third reading signal or ground potential to another one of the first and the second bit lines of the memory unit; and
sensing the signals from the first and second bit lines of the memory unit;
the programming operation comprises:
selecting at least one memory unit;
applying a first programming signal to the word line of the memory unit;
applying a second programming signal to one of the first and the second bit lines of the memory unit; and
applying a third programming signal or ground potential to another one of the first and the second bit lines of the memory unit;
the program-verifying operation comprises:
selecting at least one memory unit;
applying a reading operation to the memory unit; and then
applying a programming operation to the memory unit if the output signal is higher than a predetermined electrical level;
the self-testing operation comprises:
selecting at least one memory unit;
applying a first self-testing signal to a word line of the memory unit;
applying a second self-testing signal to the first bit line of the memory unit;
applying a third self-testing signal to the second bit line of the memory unit;
applying a reading operation to the memory unit; and
when the output signal of the memory unit is out of a predetermined signal range, the controller outputs an error or damage signal; and
the repairing operation comprises:
switching off a word line or a bit line with damaged memory units; and
selecting and switching on a redundant word line or a redundant bit line with memory redundancy for replacing the word line or the bit line with damaged memory units.

11. A memory unit, comprising:
a gate electrode;
a gate dielectric under said gate electrode;
an active area, comprising:
a first source/drain region;
a second source/drain region;
a normal field channel region formed under said gate electrode; and
an extension doping region formed between said second source/drain region and said normal field channel region;
a pre-determined code implantation region or a fringing field channel region formed between said first source/drain region and said normal field channel region; and
a metal-semiconductor compound layer formed over said gate electrode, first source/drain region and second source/drain region.

12. The memory unit as claimed in claim 11, wherein the active area is I-shape and perpendicular to a world line.

13. The memory unit as claimed in claim 11, wherein the active area is L-shape and comprises a main area and an extension area, wherein one end of the main area connects to and perpendicular to the extension area, and said main area is perpendicular to said gate electrode, and said first source/drain region is in a part of the main area, and the second source/drain region is in the extension area and a part of the main area.

14. The memory unit as claimed in claim 1, wherein the active area is J-shape and comprises a main area and a first extension area and a second extension area, with said two extension areas perpendicularly connecting to two ends of the main area respectively, and the main area of active area is perpendicular to said gate electrode, the first source/drain region is in said first extension area and in a part of the main area, and the second source/drain region is in said second extension area and a part of the main area.

15. The memory unit as claimed in claim 11, wherein the active area is T- shape and comprises a main area and an extension area, wherein the end of the main area connects to the middle of the extension area, and the active area is parallel to the first source/drain line or the first bit line corresponding thereto, and the extension area is parallel to the word line corresponding thereto, and the first source/drain region is in a part of the main area, and the second source/drain region is in the extension area and a part of the main area.

16. A plurality of memory units as claimed in claim 11, wherein their active area comprise I-shape, J-shape, L-shape, T-shape or the combination thereof.

17. A memory array, comprising
a plurality of word lines;
a plurality of first bit lines or first source/drain lines;
a plurality of second bit lines or second source/drain lines; and
a plurality of memory units, each memory unit comprising:
a gate electrode;
a gate dielectric under said gate electrode;
an active area, comprising:
a first source/drain region coupled to one first bit line or first source/drain line;
a second source/drain region coupled to one second bit line or second source/drain line;
a normal field channel region formed under said gate electrode; and
an extension doping region formed between said second source/drain region and said normal field channel region;
a pre-determined code implantation region or a fringing field channel region formed between said first source/drain region and said normal field channel region; and
a metal-semiconductor compound layer formed over said gate electrode, first source/drain region and second source/drain region.

18. The memory array as claimed in claim 17, further comprising a circuit coupled to at least one first bit line and at least one second bit line, wherein the circuit provides electrical signals to sense the conductivity between said first bit line and second bit line to determine the existence of code implantation region, is a Mask ROM.

19. The memory array as claimed in claim 17, further comprising:
a selecting/driving circuit coupled to the word lines and the bit lines to select a corresponding memory unit based on predetermined addresses;
a sensing circuit coupled to the selecting/driving circuit to amplify a voltage of data stored in the corresponding memory unit; and
a controller coupled to the selecting/driving circuit and the sensing circuit to perform memory operations on the memory units.

20. The memory array as claimed in claim 19, wherein the controller performs at least one of a plurality of operating functions including an initializing operation, a reading operation, a self-testing operation and a repairing operation, wherein
the initializing operation comprises:
selecting at least one memory unit;
applying a first initializing signal to a word line of the memory unit;
applying a second initializing signal to a first bit line of the memory unit; and
applying a third initializing signal to a second bit line of the memory unit until the output signal of the memory unit is lower than a predetermined signal level;
the reading operation comprises:
selecting at least one memory unit;
applying a first reading signal to the word line of the memory unit;
applying a second reading signal to one of the first and the second bit lines of the memory unit;
applying a third reading signal or ground potential to another one of the first and the second bit lines of the memory unit; and
sensing the signals from the first and second bit lines of the memory unit;
the self-testing operation comprises:
selecting at least one memory unit;
applying a first self-testing signal to a word line of the memory unit;
applying a second self-testing signal to the first bit line of the memory unit;
applying a third self-testing signal to the second bit line of the memory unit;
applying a reading operation to the memory unit; and
when the output signal of the memory unit is out of a predetermined signal range, the controller outputs an error or damage signal; and
the repairing operation comprises:
switching off a word line or a bit line with damaged memory units; and
selecting and switching on a redundant word line or a redundant bit line with memory redundancy for replacing the word line or the bit line with damaged memory units.

21. The memory array as-claimed in claim 17, further comprising an over- writing circuit coupled to the word lines, the first bit lines and the second bit lines, wherein the over-writing circuit provides over-write signals to select memory units and permanently alter the conductivity between said first bit line and second bit line of selected memory units as a programmed One Time Programmable ROM.

22. A memory unit, comprising:
a gate electrode;
a gate dielectric under said gate electrode;
an active area, comprising:
a first source/drain region;
a second source/drain region;
a normal field channel region formed under said gate electrode;
a fringing field channel region formed between said first source/drain region and said normal field channel region; and
an extension doping region formed between said second source/drain region and said normal field channel region;
a metal-semiconductor compound layer formed over said gate electrode, first source/drain region and second source/drain region; and
a multi-layer dielectric spacer formed onto the sidewall of said gate electrode and over said fringing field channel region to store electric charges wherein carriers can be injected from said fringing field channel and trapped in said multi-layer dielectric spacer as charge trapping memory.

23. The memory unit as claimed in claim 22, wherein the active area is I-shape and perpendicular to a world line.

24. The memory unit as claimed in claim 22, wherein the active area is L- shape and comprises a main area and an extension area, wherein one end of the main area connects to and perpendicular to the extension area, and said main area is perpendicular to said gate electrode, and said first source/drain region is in a part of the main area, and the second source/drain region is in the extension area and a part of the main area.

25. The memory unit as claimed in claim 22, wherein the active area is J-shape and comprises a main area and a first extension area and a second extension area, with said two extension areas perpendicularly connecting to two ends of the main area respectively, and the main area of active area is perpendicular to said gate electrode, the first source/drain region is in said first extension area and in a part of the main area, and the second source/drain region is in said second extension area and a part of the main area.

26. The memory unit as claimed in claim 22, wherein the active area is T- shape and comprises a main area and an extension area, wherein the end of the main area connects to the middle of the extension area, and the active area is parallel to the first source/drain line or the first bit line corresponding thereto, and the extension area is parallel to the word line corresponding thereto, and the first source/drain region is in a part of the main area, and the second source/drain region is in the extension area and a part of the main area.

27. A plurality of memory units as claimed in claim 22, wherein their active area comprise I-shape, J-shape, L-shape, T-shape or the combination thereof.

28. A memory array, comprising
a plurality of word lines;
a plurality of first bit lines or first source/drain lines;
a plurality of second bit lines or second source/drain lines; and
a plurality of memory units, each memory unit comprising:
a gate electrode coupled to one word line;
a gate dielectric under said gate electrode;
an active area, comprising:
a first source/drain region coupled to one first source/drain line or first bit line;
a second source/drain region coupled to one second source/drain line or second bit line;
a normal field channel region formed under said gate electrode;
a fringing field channel region formed between said first source/drain region and said normal field channel region; and
an extension doping region formed between said second source/drain region and said normal field channel region;
a metal-semiconductor compound layer formed over said gate electrode, first source/drain region and second source/drain region; and
a multi-layer dielectric spacer formed over said fringing field channel region to store electric charges wherein carriers can be injected from said fringing field channel and trapped in said multi-layer dielectric spacer as charge trapping memory.

29. The memory array as claimed in claim 28, further comprising a circuit coupled to at least one first bit line and at least one second bit line, wherein the circuit provides electrical signals to alter and sense the conductivity between said first bit line and second bit line to determine the existence of trapped charges in said multi-layer dielectric spacer, is an Electrically Erasable, Programmable ROM.

30. The memory array as claimed in claim 28, further comprising:
a selecting/driving circuit coupled to the word lines and the bit lines to select a corresponding memory unit based on predetermined addresses;
a sensing circuit coupled to the selecting/driving circuit to amplify a voltage of data stored in the corresponding memory unit; and
a controller coupled to the selecting/driving circuit and the sensing circuit to perform memory operations on the memory units.

31. The memory array as claimed in claim 28, wherein the controller performs at least one of a plurality of operating functions including an initializing operation, a reading operation, a programming operation, an erasing operation, a program- verifying operating, an erase-verifying operation, a self-testing operation and a repairing operation, wherein
the initializing operation comprises:
selecting at least one memory unit;
applying a first initializing signal to a word line of the memory unit;
applying a second initializing signal to a first bit line of the memory unit; and
applying a third initializing signal to a second bit line of the memory unit until the output signal of the memory unit is lower than a predetermined signal level;
the reading operation comprises:
selecting at least one memory unit;
applying a first reading signal to the word line of the memory unit;
applying a second reading signal to one of the first and the second bit lines of the memory unit;
applying a third reading signal or ground potential to another one of the first and the second bit lines of the memory unit; and
sensing the signals from the first and second bit lines of the memory unit;
the programming operation comprises:
selecting at least one memory unit;
applying a first programming signal to the word line of the memory unit;
applying a second programming signal to one of the first and the second bit lines of the memory unit; and
applying a third programming signal or ground potential to another one of the first and the second bit lines of the memory unit;
the program-verifying operation comprises:
selecting at least one memory unit;
applying a reading operation to the memory unit; and
applying a programming operation to the memory unit if the output signal is higher than a predetermined electrical level;
the erasing operation comprises:
selecting a memory unit;
applying a first erasing signal applied to a word line of the memory unit; and
applying a second erasing signal applied to a first bit line and [s1] a second bit line of the memory unit;
the erase-verifying operation comprises:
selecting at least one memory unit;
applying a reading operation to the memory unit; and
applying a erasure operation to the memory unit if the output signal is lower than a predetermined electrical level;
the self-testing operation comprises:
selecting at least one memory unit;
applying a first self-testing signal to a word line of the memory unit;
applying a second self-testing signal to the first bit line of the memory unit;
applying a third self-testing signal to the second bit line of the memory unit;
applying a reading operation to the memory unit; and
when the output signal of the memory unit is out of a predetermined signal range, the controller outputs an error or damage signal; and
the repairing operation comprises:
switching off a word line or a bit line with damaged memory units; and
selecting and switching on a redundant word line or a redundant bit line with memory redundancy for replacing the word line or the bit line with damaged memory units.

32. The memory array as claimed in claim 28, further comprising an over-writing circuit coupled to the word lines, the first bit lines and the second bit lines, wherein the over-writing circuit provides over-write signals to select memory units and permanently alter the conductivity between said first bit line and second bit line of selected memory units as a programmed One Time Programmable ROM.
